(19) United States
(12) Patent Application Publication
(10) Pub. No.: US 2026/0304908 A1
(43) Pub. Date: Oct. 1, 2026

(54) METHOD FOR MANUFACTURING SEMICONDUCTOR DEVICE, AND SEMICONDUCTOR DEVICE

(71) Applicant: Resonac Corporation, Minato-ku, Tokyo (JP)

(72) Inventors: Shintaro NAGAYAMA, Tokyo (JP); Keiichi HATAKEYAMA, Tokyo (JP); Eisaku ISHIKAWA, Tokyo (JP)

(21) Appl. No.: 19/477,784

(22) PCT Filed: Aug. 25, 2023
(86) PCT No.: PCT/JP2023/030719

§ 371 Date: Oct. 23, 2025

(51) Int. Cl. H10D 80/30; H10P 52/40; H10W 72/90; H10W 80/00; H10W 90/00

(52) U.S. Cl. CPC H10D 80/30; H10P 52/403; H10P 52/407; H10P 52/409; H10W 72/926; H10W 72/9415; H10W 72/944; H10W 72/952; H10W 80/037; H10W 80/168; H10W 80/312; H10W 80/327; H10W 90/792

(57) ABSTRACT

A method for manufacturing a semiconductor device includes: preparing a first semiconductor substrate that includes a first substrate body, a first electrode, and a first insulating layer; preparing a second semiconductor substrate that includes a second substrate body, a second electrode, and a second insulating layer; working a first surface of the first semiconductor substrate on a side opposite to the first substrate body such that the first electrode is recessed with respect to the first insulating layer; working a second surface of the second semiconductor substrate on a side opposite to the second substrate body such that the second electrode project with respect to the second insulating layer; and bonding the first electrode of the first semiconductor substrate to the second electrode of the second semiconductor substrate and bonding the first insulating layer of the first semiconductor substrate to the second insulating layer of the second semiconductor substrate.

### TECHNICAL FIELD

The present disclosure relates to a method for manufacturing a semiconductor device, and the semiconductor device.

### BACKGROUND ART

Patent Literature 1 discloses a hybrid bonding method which is a three-dimensional semiconductor mounting technology. This bonding method is a method of bonding, to a first semiconductor substrate having a terminal electrode and an insulating film, a plurality of semiconductor chips obtained by dicing a second semiconductor substrate having a terminal electrode and an insulating film. In this bonding method, firstly, surfaces of the first semiconductor substrate and the second semiconductor substrate are polished using a CMP (chemical mechanical polishing) method such that surfaces of the terminal electrodes are located at slightly lower positions than surfaces of the insulating films on both the first semiconductor substrate and the second semiconductor substrate. Next, the second semiconductor substrate is diced into the plurality of semiconductor chips as individual pieces. Next, alignment of the plurality of semiconductor chips with respect to the first semiconductor substrate is performed, and the insulating film of each of the plurality of semiconductor chips is bonded to the insulating film of the first semiconductor substrate. Next, at least either predetermined heat or pressure is applied to the first semiconductor substrate and the plurality of semiconductor chips to bond the terminal electrode of the first semiconductor substrate to the terminal electrodes of the plurality of semiconductor chips.

### CITATION LIST

### Patent Literature

Patent Literature 1: Japanese Unexamined Patent Publication No. 2021-197430

### SUMMARY OF INVENTION

### Technical Problem

In the bonding method described in Patent Literature 1, the surfaces of the terminal electrodes are located at slightly lower positions than the surfaces of the insulating films in both the first semiconductor substrate and the second semiconductor substrate, and a large stress is thus generated in the insulating film of the first semiconductor substrate and the insulating films of the plurality of semiconductor chips when at least either predetermined heat or pressure is applied to bond the terminal electrode of the first semiconductor substrate and the terminal electrodes of the plurality of semiconductor chips. Therefore, a residual stress of the insulating film in the manufactured semiconductor device is large, and reliability thereof tends to be low.

Since the surfaces of the terminal electrodes are located at slightly lower positions than the surfaces of the insulating films in both the first semiconductor substrate and the second semiconductor substrate, it is difficult to align the plurality of semiconductor chips with respect to the first semiconductor substrate.

An object of the present disclosure is to provide a method for manufacturing a semiconductor device capable of enhancing reliability of insulating layers, and a semiconductor device with high reliability of insulating layers.

### Solution to Problem

The present disclosure relates to, as one aspect, a method for manufacturing a semiconductor device. A method for manufacturing a semiconductor device includes: preparing a first semiconductor substrate that includes a first substrate body, a first electrode disposed on the first substrate body, and a first insulating layer disposed around the first electrode on the first substrate body; preparing a second semiconductor substrate that includes a second substrate body, a second electrode disposed on the second substrate body, and a second insulating layer disposed around the second electrode on the second substrate body; working a first surface of the first semiconductor substrate on a side opposite to the first substrate body such that the first electrode is recessed with respect to the first insulating layer; working a second surface of the second semiconductor substrate on a side opposite to the second substrate body such that the second electrode project with respect to the second insulating layer; and bonding the first electrode of the first semiconductor substrate to the second electrode of the second semiconductor substrate and bonding the first insulating layer of the first semiconductor substrate to the second insulating layer of the second semiconductor substrate.

In this method for manufacturing a semiconductor device, the first surface of the first semiconductor substrate is worked such that the first electrode is recessed with respect to the first insulating layer, and recessed portions obtained by the first electrode being recessed with respect to the first insulating layer are thus formed on the first surface of the first semiconductor substrate. In addition, the second surface of the second semiconductor substrate is worked such that the second electrode project with respect to the second insulating layer, and projecting portions obtained by the second electrode projecting with respect to the second insulating layer are thus formed on the second surface of the second semiconductor substrate. Therefore, it is possible to fit the projecting portions formed on the second surface of the second semiconductor substrate into the recessed portions formed on the first surface of the first semiconductor substrate when the first semiconductor substrate and the second semiconductor substrate are caused to overlap each other. In this manner, when the first semiconductor substrate and the second semiconductor substrate are bonded to each other, the amounts of expansion/contraction (the amounts of expansion or the amounts of contraction) of the first insulating layer and the second insulating layer decrease as compared with a case where both the first electrode and the second electrode are recessed or project with respect to the first insulating layer and the second insulating layer, and stresses generated in the first insulating layer and the second insulating layer are alleviated. It is thus possible to manufacture a semiconductor device with high reliability of the first insulating layer and the second insulating layer. Moreover, it is possible to easily align the first semiconductor substrate with the second semiconductor substrate by fitting the projecting portions formed on the second surface of the second semiconductor substrate into the recessed portions formed on the first surface of the first semiconductor substrate.

In the above-described method for manufacturing a semiconductor device, the first electrode and the second electrode may be formed of copper. In this method for manufacturing a semiconductor device, the first electrode and the second electrode are formed of copper, and it is thus possible to manufacture a semiconductor device with excellent conductivity.

In the above-described method for manufacturing a semiconductor device, the first surface may be polished using a CMP method in the working of the first surface. In this method for manufacturing a semiconductor device, it is possible to easily cause the first electrode to be recessed with respect to the first insulating layer by polishing the first surface using the CMP method.

In the above-described method for manufacturing a semiconductor device, the second surface may be polished using a CMP method in the working of the second surface. In this method for manufacturing a semiconductor device, it is possible to easily cause the second electrode to project with respect to the second insulating layer by polishing the second surface using the CMP method.

In the above-described method for manufacturing a semiconductor device, the bonding may include activating the first surface and the second surface. In this method for manufacturing a semiconductor device, it is possible to easily bond the first electrode to the second electrode and to easily bond the first insulating layer to the second insulating layer by activating the first surface and the second surface.

In the above-described method for manufacturing a semiconductor device, the bonding includes aligning the first semiconductor substrate with the second semiconductor substrate by fitting projecting portions formed on the second surface and obtained by the second electrode projecting with respect to the second insulating layer into recessed portions formed on the first surface and obtained by the first electrode being recessed with respect to the first insulating layer. In this method for manufacturing a semiconductor device, it is possible to easily align the first semiconductor substrate with the second semiconductor substrate by fitting the projecting portions formed on the second surface into the recessed portions formed on the first surface.

In the above-described method for manufacturing a semiconductor device, the first insulating layer may be formed of an inorganic insulating material. In this method for manufacturing a semiconductor device, the first insulating layer is formed of an inorganic insulating material, and it is thus possible to firmly bond the first insulating layer to the second insulating layer by the first insulating layer biting (trapping) foreign matters such as particles even if the foreign matters are present on the first insulating layer or the second insulating layer.

In the above-described method for manufacturing a semiconductor device, the first insulating layer may be formed of an organic insulating material. In this method for manufacturing a semiconductor device, the first insulating layer is formed of an organic insulating material, and it is thus possible to bond the first insulating layer to the second insulating layer even at a low temperature. This leads to enhanced reliability of the semiconductor device.

In the above-described method for manufacturing a semiconductor device, the second insulating layer may be formed of an inorganic insulating material. In this method for manufacturing a semiconductor device, the second insulating layer is formed of an inorganic insulating material, and it is thus possible to firmly bond the first insulating layer to the second insulating layer by the second insulating layer biting (trapping) foreign matters such as particles even if the foreign matters are present on the first insulating layer or the second insulating layer.

In the above-described method for manufacturing a semiconductor device, the second insulating layer may be formed of an organic insulating material. In this method for manufacturing a semiconductor device, the second insulating layer is formed of an organic insulating material, and it is thus possible to bond the first insulating layer to the second insulating layer even at a low temperature. This leads to enhanced reliability of the semiconductor device.

In the above-described method for manufacturing a semiconductor device, the first semiconductor substrate may be a semiconductor wafer or a semiconductor chip obtained by singulating a semiconductor wafer.

In the above-described method for manufacturing a semiconductor device, the second semiconductor substrate may be a semiconductor wafer or a semiconductor chip obtained by singulating a semiconductor wafer.

In the above-described method for manufacturing a semiconductor device, the first semiconductor substrate may be disposed above the second semiconductor substrate, or the second semiconductor substrate may be disposed above the first semiconductor substrate in the bonding.

The present disclosure relates to, as another aspect, a semiconductor device. A semiconductor device includes: a first semiconductor substrate including a first substrate body, a first electrode disposed on the first substrate body, and a first insulating layer disposed around the first electrode on the first substrate body; and a second semiconductor substrate including a second substrate body, a second electrode disposed on the second substrate body, and a second insulating layer disposed around the second electrode on the second substrate body, in which the first electrode of the first semiconductor substrate and the second electrode of the second semiconductor substrate are bonded to each other, and the first insulating layer of the first semiconductor substrate and the second insulating layer of the second semiconductor substrate are bonded to each other, and a first bonded surface between the first electrode and the second electrode is located closer to the side of the first substrate body than a second bonded surface between the first insulating layer and the second insulating layer.

In this semiconductor device, the first bonded surface between the first electrode and the second electrode is located closer to the side of the first substrate body than the second bonded surface between the first insulating layer and the second insulating layer. In other words, the semiconductor device is manufactured by fitting projecting portions 25 of the second semiconductor substrate obtained by the second electrode projecting with respect to the second insulating layer into recessed portions of the first semiconductor substrate obtained by the first electrode being recessed with respect to the first insulating layer and thereby bonding the first semiconductor substrate to the second semiconductor substrate. In other words, stresses generated in the first insulating layer and the second insulating layer when the first semiconductor substrate and the second semiconductor substrate are bonded to each other are alleviated. This leads to high reliability of the first insulating layer and the second insulating layer.

In the above-described semiconductor device, shear strength of the first insulating layer and the second insulating layer may be equal to or greater than 25 MPa and equal to or less than 35 MPa. In this semiconductor device, the shear strength of the first insulating layer and the second insulating layer is equal to or greater than 25 MPa and equal to or less than 35 MPa, which leads to high reliability of the first insulating layer and the second insulating layer. The shear strength of the first insulating layer and the second insulating layer can be set to be equal to or greater than 25 MPa and equal to or less than 35 MPa by manufacturing the semiconductor device by the aforementioned method.

The present disclosure relates to, as another aspect, a semiconductor device. A semiconductor device includes: a first substrate body; a first electrode disposed on the first substrate body; a second substrate body; a second electrode disposed on the second substrate body and bonded to the first electrode; and an insulating layer disposed around the first electrode and the second electrode between the first substrate body and the second substrate body, in which shear strength of the insulating layer is equal to or greater than 25 MPa and equal to or less than 35 MPa.

In this semiconductor device, the shear strength of the insulating layer is equal to or greater than 25 MPa and equal to or less than 35 MPa, which leads to high reliability of the insulating layer. Note that the shear strength of the insulating layer can be set to be equal to or greater than 25 MPa and equal to or less than 35 MPa by manufacturing the semiconductor device by the aforementioned method.

### Advantageous Effects of Invention

According to one aspect of the present disclosure, it is possible to enhance reliability of insulating layers.

### BRIEF DESCRIPTION OF DRAWINGS

FIG. 1 is a sectional view schematically illustrating an example of a semiconductor device manufactured by a method for manufacturing a semiconductor device according to an embodiment of the present disclosure.

FIGS. 2(a), 2(b), and 2(c) are schematic sectional views sequentially illustrating the method for manufacturing the semiconductor device illustrated in FIG. 1.

FIGS. 3(a), 3(b), and 3(c) are schematic sectional views sequentially illustrating the method for manufacturing the semiconductor device illustrated in FIG. 1.

FIG. 4 is a schematic sectional view illustrating the method for manufacturing the semiconductor device illustrated in FIG. 1.

FIG. 5 is a schematic sectional view illustrating the method for manufacturing the semiconductor device illustrated in FIG. 1.

FIG. 6 is a schematic sectional view illustrating another method for manufacturing the semiconductor device illustrated in FIG. 1.

FIG. 7 is a schematic sectional view illustrating another method for manufacturing the semiconductor device illustrated in FIG. 1.

### DESCRIPTION OF EMBODIMENTS

Hereinafter, some embodiments of the present disclosure will be described in detail with reference to the drawings as necessary. In the following description, the same or corresponding portions will be denoted by the same reference numerals, and redundant description will be omitted. Furthermore, unless otherwise specified, positional relationships such as up, down, left, and right are based on the positional relationships illustrated in the drawings. The use of the terms “left”, “right”, “front”, “back”, “up”, “down”, “above”, “below”, and the like in the description and claims of this specification is intended for description and is not necessarily meant to indicate a permanent relative position thereof. Furthermore, the dimensional ratios in the drawings are not limited to the illustrated ratios.

The term “layer” herein includes a structure with a partially formed shape in addition to a structure with a shape formed on an entire surface in observation in plan view. In the present specification, the term “process” includes not only an independent process but also a process that cannot be clearly distinguished from other processes as long as an intended action of the process is achieved. In addition, a numerical range using “to” indicates a range including numerical values described before and after “to” as a minimum value and a maximum value. In numerical ranges described in stages in the present specification, an upper limit value or a lower limit value described for one numerical range may be replaced with an upper limit value or a lower limit value for a numerical range described in another stage. For a numerical range described in the present specification, an upper limit value or a lower limit value of the numerical range may be replaced with a value shown in examples.

### Configuration of Semiconductor Device

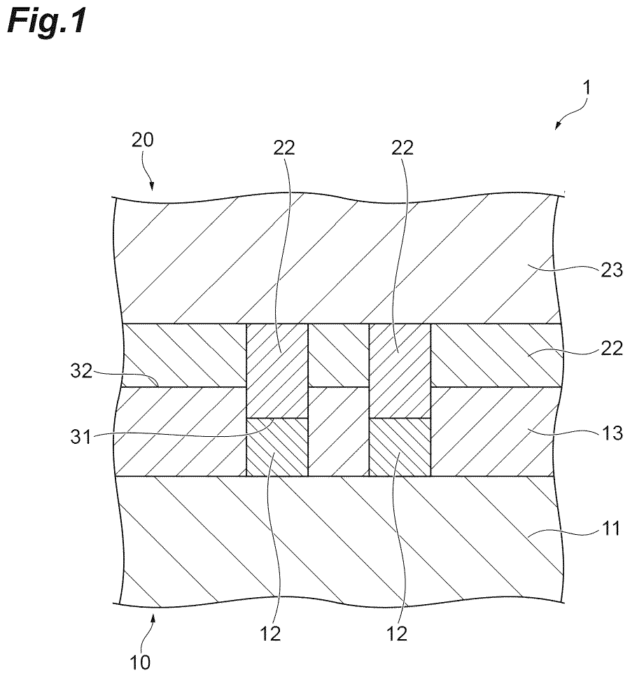

FIG. 1 is a sectional view schematically illustrating an example of a semiconductor device manufactured by a manufacturing method according to the present embodiment. As illustrated in FIG. 1, a semiconductor device 1 includes a first semiconductor substrate 10 and a second semiconductor substrate 20 bonded to the first semiconductor substrate 10. Each of the first semiconductor substrate 10 and the second semiconductor substrate 20 is a semiconductor wafer provided with semiconductor chips such as LSI (large scale integrated) circuit chips or CMOS (complementary metal oxide semiconductor) sensors or a plurality of semiconductor elements constituting functional circuits corresponding to the semiconductor chips. The semiconductor chips are obtained by singulating a semiconductor wafer by a cutting way such as dicing. As a method of singulating the semiconductor wafer, it is possible to use, for example, plasma dicing, stealth dicing, or laser dicing.

The semiconductor device 1 may have a structure of W2W (wafer to wafer), C2C (chip to chip), or C2W (chip to wafer) by combining the first semiconductor substrate 10 and the second semiconductor substrate 20 with semiconductor wafers and semiconductor chips. In other words, when both the first semiconductor substrate 10 and the second semiconductor substrate 20 are semiconductor wafers, the semiconductor device 1 has a structure of W2W. When both the first semiconductor substrate 10 and the second semiconductor substrate 20 are semiconductor chips, the semiconductor device 1 has a structure of C2C. When the first semiconductor substrate 10 is a semiconductor wafer and the second semiconductor substrate 20 is a semiconductor chip, or when the first semiconductor substrate 10 is a semiconductor chip and the second semiconductor substrate 20 is a semiconductor wafer, the semiconductor device 1 has a structure of C2W.

The first semiconductor substrate 10 includes a first substrate body 11, a plurality of first electrodes 12 disposed on the first substrate body 11, and a first insulating layer 13 disposed around the first electrodes 12 on the first substrate body 11. The second semiconductor substrate 20 includes a second substrate body 21, a plurality of second electrodes 22 disposed on the second substrate body 21, and a second insulating layer 23 disposed around the second electrodes 22 on the second substrate body 21. In the semiconductor device 1, the plurality of first electrodes 12 of the first semiconductor substrate 10 and the plurality of second electrodes 22 of the second semiconductor substrate 20 are directly bonded to each other. In the semiconductor device 1, the first insulating layer 13 of the first semiconductor substrate 10 and the second insulating layer 23 of the second semiconductor substrate 20 are directly bonded to each other. The insulating layers constituted by the first insulating layer 13 and the second insulating layer 23 are disposed around the plurality of first electrodes 12 and the plurality of second electrodes 22 between the first substrate body 11 and the second substrate body 21. The bonded surfaces between the plurality of first electrodes 12 of the first semiconductor substrate 10 and the plurality of second electrodes 22 of the second semiconductor substrate 20 will be referred to as first bonded surfaces 31. The bonded surface between the first insulating layer 13 of the first semiconductor substrate 10 and the second insulating layer 23 of the second semiconductor substrate 20 will be referred to as second bonded surface 32.

The first substrate body 11 is provided with semiconductor elements (not illustrated). The second substrate body 21 is provided with semiconductor elements (not illustrated).

The plurality of first electrodes 12 are electrodes that are electrically connected to the semiconductor elements provided on the first substrate body 11 and penetrate through the first insulating layer 13. The plurality of first electrodes 12 are formed of, for example, conductive metal such as copper (Cu). The plurality of second electrodes 22 are electrodes that are electrically connected to the semiconductor elements provided on the second substrate body 21 and penetrate through the second insulating layer 23. The plurality of second electrodes 22 are formed of, for example, conductive metal such as copper (Cu), similarly to the plurality of first electrodes 12.

The first insulating layer 13 is an insulating layer provided on the first substrate body 11. The first insulating layer 13 is formed of an inorganic insulating material or an organic insulating material. The second insulating layer 23 is an insulating layer provided on the second substrate body 21. The second insulating layer 23 is formed of an inorganic insulating material or an organic insulating material, similarly to the first insulating layer 13.

Inorganic insulating materials forming the first insulating layer 13 and the second insulating layer 23 may be, for example, silicon dioxide (SiO₂), silicon nitride (SiN), or silicon oxynitride (SiON). In a case where the first insulating layer 13 and the second insulating layer 23 are formed of inorganic insulating materials, the inorganic insulating material forming the first insulating layer 13 and the inorganic insulating material forming the second insulating layer 23 may be the same or different.

Organic insulating materials forming the first insulating layer 13 and the second insulating layer 23 may be, for example, polyimide, a polyimide precursor (for example, a polyimide amic ester or a polyamic acid), polyamideimide, benzocyclobutene (BCB), polybenzoxazole (PBO), a PBO precursor, polydimethylsiloxane (PDMS), an epoxy resin, a phenol resin, or a silicone resin. The organic insulating materials forming the first insulating layer 13 and the second insulating layer 23 may contain a photosensitive resin or a thermosetting resin. The organic insulating materials forming the first insulating layer 13 and the second insulating layer 23 have a lower elastic modulus than inorganic materials such as silicon oxide (SiO₂). The elastic modulus of the organic insulating materials is, for example, equal to or less than 7.0 GPa, and is preferably equal to or less than 5.0 GPa or equal to or less than 3.0 GPa. The elastic modulus described here means Young's modulus. In a case where the first insulating layer 13 and the second insulating layer 23 are formed of organic insulating materials, the organic insulating material forming the first insulating layer 13 and the organic insulating material forming the second insulating layer 23 may be the same or different.

### Method for Manufacturing Semiconductor Device

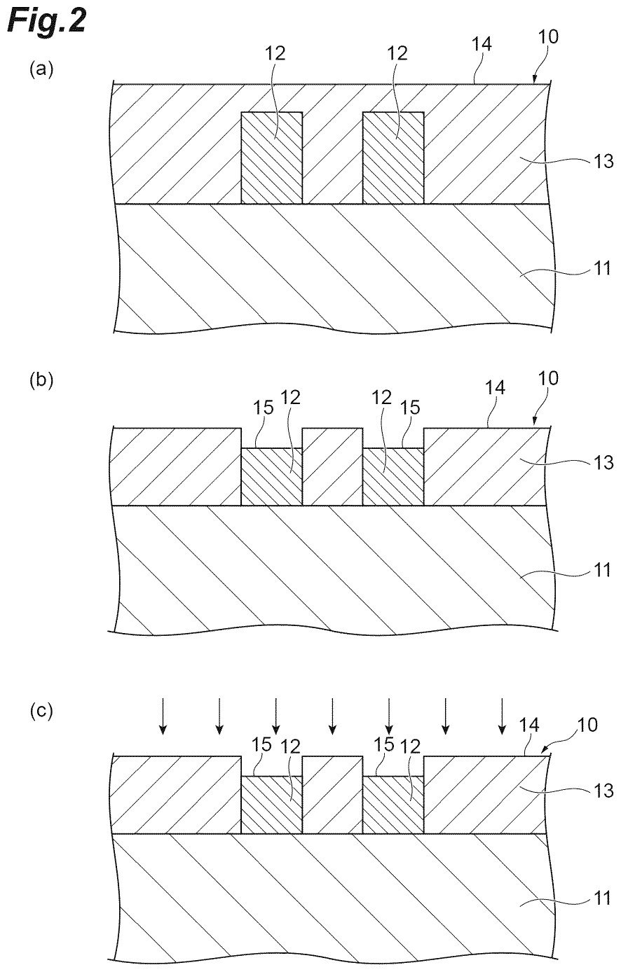

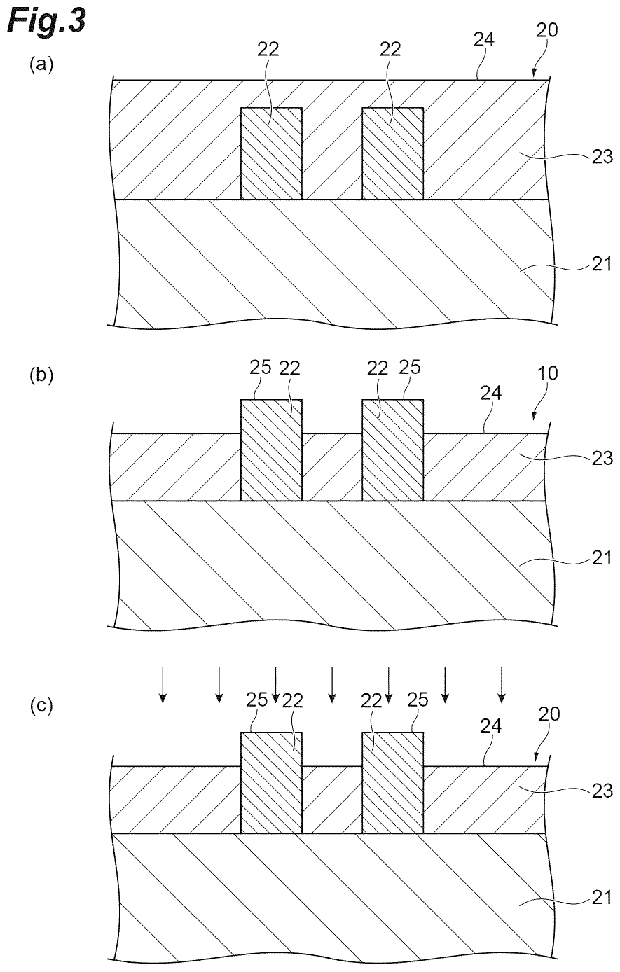

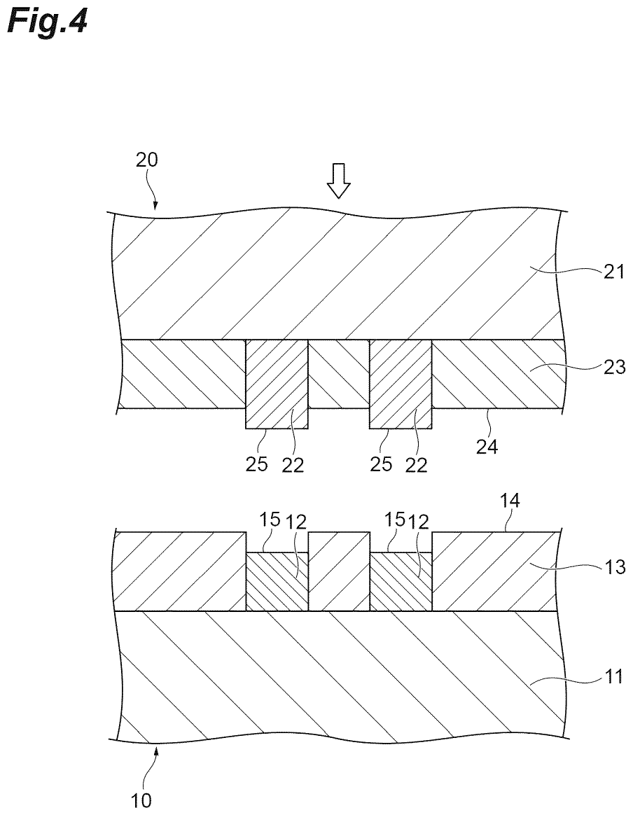

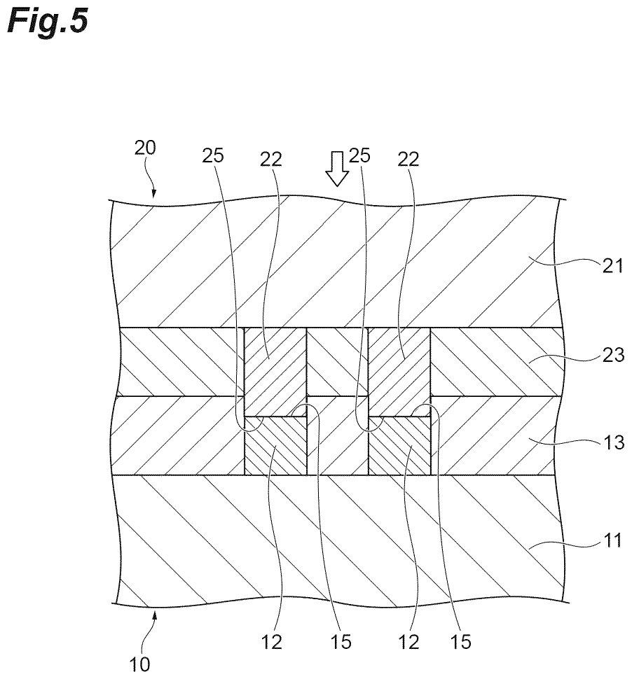

Next, a method for manufacturing the semiconductor device 1 will be described with reference to FIGS. 2 to 5. FIGS. 2(a), 2(b), and 2(c) are schematic sectional views sequentially illustrating a method for manufacturing the semiconductor device illustrated in FIG. 1. FIGS. 3(a), 3(b), and 3(c) are schematic sectional views sequentially illustrating the method for manufacturing the semiconductor device illustrated in FIG. 1. FIG. 4 is a schematic sectional view illustrating the method for manufacturing the semiconductor device illustrated in FIG. 1. FIG. 5 is a schematic sectional view illustrating the method for manufacturing the semiconductor device illustrated in FIG. 1.

The semiconductor device 1 can be manufactured through, for example, the following processes (a) to (d):
(a) a process of preparing (providing) the first semiconductor substrate 10 (see FIG. 2);
(b) a process of preparing (providing) the second semiconductor substrate 20 (see FIG. 3);
(c) a process of working a first surface 14 of the first semiconductor substrate 10 on the side opposite to the first substrate body 11 (see FIG. 2);
(d) a process of working a second surface 24 of the second semiconductor substrate 20 on the side opposite to the second substrate body 21 (see FIG. 2); and
(e) a process of bonding the first semiconductor substrate 10 to the second semiconductor substrate 20 (see FIGS. 2 to 5).
   [Process (a)]

The process (a) is a process of preparing the first semiconductor substrate 10 that includes the first substrate body 11, the plurality of first electrodes 12 disposed on the first substrate body 11, and the first insulating layer 13 disposed around the plurality of first electrodes 12 on the first substrate body 11. In the process (a), the plurality of first electrodes 12 are formed on the first substrate body 11 first. The plurality of first electrodes 12 are formed of, for example, conductive metal such as copper (Cu). Once the formation of the plurality of first electrodes 12 ends, the first insulating layer 13 is formed on the first substrate body 11, and the plurality of first electrodes 12 are covered with the first insulating layer 13, as illustrated in FIG. 2(a). The first insulating layer 13 is formed of, for example, for example, an inorganic insulating material such as silicon dioxide (SiO₂), silicon nitride (SiN) or silicon oxynitride (SiON), or an organic insulating material such as polyimide, a polyimide precursor (for example, a polyimide amic ester or a polyamic acid), polyamideimide, benzocyclobutene (BCB), polybenzoxazole (PBO), a PBO precursor, polydimethylsiloxane (PDMS), an epoxy resin, a phenol resin, or a silicone resin.

[Process (b)]

The process (b) is a process of preparing the second semiconductor substrate 20 that includes the second substrate body 21, the plurality of second electrodes 22 disposed on the second substrate body 21, and the second insulating layer 23 disposed around the plurality of second electrodes 22 on the second substrate body 21. In the process (b), the plurality of second electrodes 22 are formed on the second substrate body 21 first. The plurality of second electrodes 22 are formed of, for example, conductive metal such as copper (Cu). Once the formation of the second electrodes 22 ends, the second insulating layer 23 is formed on the second substrate body 21, and the plurality of second electrodes 22 are covered with the second insulating layer 23, as illustrated in FIG. 3(a). The second insulating layer 23 is formed of, for example, for example, an inorganic insulating material such as silicon dioxide (SiO₂), silicon nitride (SiN) or silicon oxynitride (SiON), or an organic insulating material such as polyimide, a polyimide precursor (for example, a polyimide amic ester or a polyamic acid), polyamideimide, benzocyclobutene (BCB), polybenzoxazole (PBO), a PBO precursor, polydimethylsiloxane (PDMS), an epoxy resin, a phenol resin, or a silicone resin.

[Process (c)]

The process (c) is a process of working the first surface 14 of the first semiconductor substrate 10 on the side opposite to the first substrate body 11 such that the plurality of first electrodes 12 are recessed with respect to the first insulating layer 13. The first surface 14 is a surface of the first semiconductor substrate 10 on the side of the plurality of first electrodes 12 and the first insulating layer 13 with respect to the first substrate body 11. The working of the first surface 14 is performed by polishing the first surface 14 using, for example, a chemical mechanical polishing (CMP) method. At this time, the first surface 14 can be polished such that the plurality of first electrodes 12 are recessed with respect to the first insulating layer 13 by adjusting a component or the like of a slurry used for the polishing of the first surface 14, adjusting a polishing torque of the first surface 14, or optimizing a polishing pad for polishing the first surface 14, for example. A plurality of recessed portions 15 obtained by the plurality of first electrodes 12 being recessed with respect to the first insulating layer 13 are formed on the first surface 14 of the first semiconductor substrate 10 through the working of the first surface 14.

[Process (d)]

The process (d) is a process of working the second surface 24 of the second semiconductor substrate 20 on the side opposite to the second substrate body 21 such that the plurality of second electrodes 22 project with respect to the second insulating layer 23. The second surface 24 is a surface of the second semiconductor substrate 20 on the side of the plurality of second electrodes 22 and the second insulating layer 23 with respect to the second substrate body 21. The working of the second surface 24 is performed by polishing the second surface 24 using, for example, the CMP method. At this time, the second surface 24 can be polished such that the plurality of second electrodes 22 project with respect to the second insulating layer 23 by adjusting a component or the like of a slurry used for the polishing of the second surface 24, adjusting a polishing torque of the second surface 24, or optimizing a polishing pad for polishing the second surface 24, for example. A plurality of projecting portions 25 obtained by the plurality of second electrodes 22 projecting with respect to the second insulating layer 23 are formed on the second surface 24 of the second semiconductor substrate 20 through the working of the second surface 24.

[Process (e)]

The process (e) is a process of bonding the plurality of first electrodes 12 of the first semiconductor substrate 10 to the plurality of second electrodes 22 of the second semiconductor substrate 20 and bonding the first insulating layer 13 of the first semiconductor substrate 10 to the second insulating layer 23 of the second semiconductor substrate 20.

In the process (e), a process of activating the first surface 14 and the second surface 24 is performed as illustrated in FIGS. 2(c) and 3(c) first. In this process, the first surface 14 and the second surface 24 are activated by performing ultraviolet irradiation, electron beam irradiation, ozone water treatment, corona discharge treatment, plasma treatment, or the like on the first surface 14 and the second surface 24, for example. Foreign matters such as particles on the first surface 14 and the second surface 24 are removed by activating the first surface 14 and the second surface 24.

Once the activation of the first surface 14 and the second surface 24 ends, a process of aligning the first semiconductor substrate 10 and the second semiconductor substrate 20 is performed as illustrated in FIG. 4. In this process, the first semiconductor substrate 10 is disposed on the bottom side, and the inverted second semiconductor substrate 20 is disposed on the top side. In other words, the second semiconductor substrate 20 is inverted, and the second semiconductor substrate 20 is disposed above the first semiconductor substrate 10. Then, the first semiconductor substrate 10 and the second semiconductor substrate 20 are aligned by fitting the projecting portions 25 formed on the second surface 24 of the second semiconductor substrate 20 into the recessed portions 15 formed on the first surface 14 of the first semiconductor substrate 10 in this state as illustrated in FIGS. 4 and 5. In other words, the plurality of first electrodes 12 of the first semiconductor substrate 10 and the plurality of second electrodes 22 of the second semiconductor substrate 20 are aligned.

Once the alignment of the first semiconductor substrate 10 and the second semiconductor substrate 20 ends, the plurality of first electrodes 12 of the first semiconductor substrate 10 and the plurality of second electrodes 22 of the second semiconductor substrate 20 are bonded to each other, and the first insulating layer 13 of the first semiconductor substrate 10 and the second insulating layer 23 of the second semiconductor substrate 20 are bonded to each other, as illustrated in FIG. 5. The bonding between the plurality of first electrodes 12 and the plurality of second electrodes 22 and the bonding between the first insulating layer 13 and the second insulating layer 23 are performed by applying either predetermined heat or pressure or both the predetermined heat and pressure to the first semiconductor substrate 10 and the second semiconductor substrate 20, for example.

In a case where the first insulating layer 13 is formed of an inorganic insulating material and the second insulating layer 23 is formed of an organic insulating material, the heating temperature of the first semiconductor substrate 10 and the second semiconductor substrate 20 can be, for example, equal to or greater than 50 °C and equal to or less than 350 °C, and the pressurizing pressure of the first semiconductor substrate 10 and the second semiconductor substrate 20 can be, for example, equal to or greater than 0.1 MPa and equal to or less than 5.0 MPa.

In a case where the first insulating layer 13 is formed of an organic insulating material and the second insulating layer 23 is formed of an inorganic insulating material, the heating temperature of the first semiconductor substrate 10 and the second semiconductor substrate 20 can be, for example, equal to or greater than 50 °C and equal to or less than 350 °C, and the pressurizing pressure of the first semiconductor substrate 10 and the second semiconductor substrate 20 can be, for example, equal to or greater than 0.1 MPa and equal to or less than 5.0 MPa.

In a case where both the first insulating layer 13 and the second insulating layer 23 are formed of inorganic insulating materials, the heating temperature of the first semiconductor substrate 10 and the second semiconductor substrate 20 can be, for example, equal to or greater than 50 °C and equal to or less than 350 °C, and the pressurizing pressure of the first semiconductor substrate 10 and the second semiconductor substrate 20 can be, for example, equal to or greater than 0.1 MPa and equal to or less than 5.0 MPa.

In a case where both the first insulating layer 13 and the second insulating layer 23 are formed of organic insulating materials, the heating temperature of the first semiconductor substrate 10 and the second semiconductor substrate 20 can be, for example, equal to or greater than 50 °C and equal to or less than 350 °C, and the pressurizing pressure of the first semiconductor substrate 10 and the second semiconductor substrate 20 can be, for example, equal to or greater than 0.1 MPa and equal to or less than 5.0 MPa.

The plurality of first electrodes 12 and the plurality of second electrodes 22 are bonded, and the first insulating layer 13 and the second insulating layer 23 are bonded, through such bonding processing. Once the bonding between the first semiconductor substrate 10 and the second semiconductor substrate 20 ends, the semiconductor device 1 is obtained. In a case where at least one of the first semiconductor substrate 10 and the second semiconductor substrate 20 is a semiconductor wafer, individual semiconductor devices can be obtained by singulating the obtained semiconductor device 1 by a cutting mechanism such as dicing, for example. As a method of singulating the semiconductor device 1, it is possible to use plasma dicing, stealth dicing, or laser dicing, for example.

In the semiconductor device 1 manufactured in this manner, the first bonded surfaces 31 which are bonded surfaces between the plurality of first electrodes 12 and the plurality of second electrodes 22 are located closer to the side of the first substrate body 11 than the second bonded surface 32 which is a bonded surface between the first insulating layer 13 and the second insulating layer 23. Note that in a case where the first insulating layer 13 is formed of an inorganic insulating material while the second insulating layer 23 is formed of an organic insulating material, in a case where the first insulating layer 13 is formed of an organic insulating material while the second insulating layer 23 is formed of an inorganic insulating material, and in a case where both the first insulating layer 13 and the second insulating layer 23 are formed of inorganic insulating materials, an interface between the first insulating layer 13 and the second insulating layer 23 is formed on the second bonded surface 32. On the other hand, in a case where both the first insulating layer 13 and the second insulating layer 23 are formed of organic insulating materials, the interface between the first insulating layer 13 and the second insulating layer 23 may not be formed on the second bonded surface 32, and there may be no boundary between the first insulating layer 13 and the second insulating layer 23.

In the semiconductor device 1 manufactured in this manner, the shear strength of the first insulating layer 13 and the second insulating layer 23 is equal to or greater than 25 MPa and equal to or less than 35 MPa. In other words, the shear strength of the insulating layers disposed around the first electrodes 12 and the second electrodes 22 between the first substrate body 11 and the second substrate body 21 is equal to or greater than 25 MPa and equal to or less than 35 MPa. The shear strength of the first insulating layer 13 and the second insulating layer 23 (the shear strength of the insulating layers) is measured by a universal bond tester (Royce 650, manufactured by Royce Instruments) after the first insulating layer 13 and the second insulating layer 23 (insulating layers) are exposed to an environment (Moisture Sensitivity Level 3 (MSL3), 30 °C, 60 RH %, 192 hours) defined by JEDEC and is caused to absorb moisture.

As described above, according to the method for manufacturing a semiconductor device of the present embodiment, the first surface 14 of the first semiconductor substrate 10 is worked such that the plurality of first electrodes 12 are recessed with respect to the first insulating layer 13, and the plurality of recessed portions 15 obtained by the plurality of first electrodes 12 being recessed with respect to the first insulating layer 13 are thus formed on the first surface 14 of the first semiconductor substrate 10. In addition, the second surface 24 of the second semiconductor substrate 20 is worked such that the plurality of second electrodes 22 project with respect to the second insulating layer 23, and the plurality of projecting portions 25 obtained by the plurality of second electrodes 22 projecting with respect to the second insulating layer 23 are thus formed on the second surface 24 of the second semiconductor substrate 20. Therefore, it is possible to fit the plurality of projecting portions 25 formed on the second surface 24 of the second semiconductor substrate 20 into the plurality of recessed portions 15 formed on the first surface 14 of the first semiconductor substrate 10 when the first semiconductor substrate 10 and the second semiconductor substrate 20 are caused to overlap each other. In this manner, when the first semiconductor substrate 10 and the second semiconductor substrate 20 are bonded to each other, the amounts of expansion/contraction (the amounts of expansion or the amounts of contraction) of the first insulating layer 13 and the second insulating layer 23 decrease as compared with a case where both the plurality of first electrodes and the plurality of second electrodes are recessed or project with respect to the first insulating layer and the second insulating layer, and stresses generated in the first insulating layer 13 and the second insulating layer 23 are alleviated. It is thus possible to manufacture the semiconductor device 1 with high reliability of the first insulating layer 13 and the second insulating layer 23. Moreover, it is possible to easily align the first semiconductor substrate 10 with the second semiconductor substrate 20 by fitting the plurality of projecting portions 25 formed on the second surface 24 of the second semiconductor substrate 20 into the recessed portions 15 formed on the first surface 14 of the first semiconductor substrate 10.

According to the method for manufacturing a semiconductor device of the present embodiment, the plurality of first electrodes 12 and the plurality of second electrodes 22 are formed of copper, and it is thus possible to manufacture the semiconductor device 1 with excellent conductivity.

Also, according to the method for manufacturing a semiconductor device of the present embodiment, it is possible to easily cause the plurality of first electrodes 12 to be recessed with respect to the first insulating layer 13 by polishing the first surface 14 using the CMP method.

Also, according to the method for manufacturing a semiconductor device of the present embodiment, it is possible to easily cause the plurality of second electrodes 22 to project with respect to the second insulating layer 23 by polishing the second surface 24 using the CMP method.

Moreover, according to the method for manufacturing a semiconductor device of the present embodiment, it is possible to easily bond the plurality of first electrodes 12 to the plurality of second electrodes 22 and to easily bond the first insulating layer 13 to the second insulating layer 23 by activating the first surface 14 and the second surface 24.

Moreover, according to the method for manufacturing a semiconductor device of the present embodiment, it is possible to easily align the first semiconductor substrate 10 with the second semiconductor substrate 20 by fitting the plurality of projecting portions 25 formed on the second surface 24 into the recessed portions 15 formed on the first surface 14.

Also, according to the method for manufacturing a semiconductor device of the present embodiment, it is possible to firmly bond the first insulating layer 13 to the second insulating layer 23 by the first insulating layer 13 biting (trapping) foreign matters such as particles even if the foreign matters are present on the first insulating layer 13 or the second insulating layer 23 by the first insulating layer 13 being formed of an inorganic insulating material.

Furthermore, according to the method for manufacturing a semiconductor device of the present embodiment, it is possible to bond the first insulating layer 13 to the second insulating layer 23 even without setting a high temperature by the first insulating layer 13 being formed of an organic insulating material. This leads to enhanced reliability of the semiconductor device 1.

Also, according to the method for manufacturing a semiconductor device of the present embodiment, it is possible to firmly bond the first insulating layer 13 to the second insulating layer 23 by the second insulating layer 23 biting (trapping) foreign matters such as particles even if the foreign matters are present on the first insulating layer 13 or the second insulating layer 23 by the second insulating layer 23 being formed of an inorganic insulating material.

Furthermore, according to the method for manufacturing a semiconductor device of the present embodiment, it is possible to bond the first insulating layer 13 to the second insulating layer 23 even without setting a high temperature by the second insulating layer 23 being formed of an organic insulating material. This leads to enhanced reliability of the semiconductor device 1.

In addition, according to the method for manufacturing a semiconductor device of the present embodiment, the first semiconductor substrate 10 is a semiconductor wafer or a semiconductor chip while the second semiconductor substrate 20 is a semiconductor wafer or a semiconductor chip, and it is thus possible to increase variations of the semiconductor device 1 and variations of the method for manufacturing the semiconductor device 1.

According to the semiconductor device 1 of the present embodiment, the first bonded surfaces 31 between the plurality of first electrodes 12 and the plurality of second electrodes 22 are located closer to the side of the first substrate body 11 than the second bonded surface 32 between the first insulating layer 13 and the second insulating layer 23. In other words, the semiconductor device 1 is manufactured by fitting the plurality of projecting portions 25 of the second semiconductor substrate 20 obtained by the plurality of second electrodes 22 projecting with respect to the second insulating layer 23 into the plurality of recessed portions 15 of the first semiconductor substrate 10 obtained by the plurality of first electrodes 12 being recessed with respect to the first insulating layer 13 and thereby bonding the first semiconductor substrate 10 to the second semiconductor substrate 20. In other words, stresses generated in the first insulating layer 13 and the second insulating layer 23 when the first semiconductor substrate 10 and the second semiconductor substrate 20 are bonded to each other are alleviated. This leads to high reliability of the first insulating layer 13 and the second insulating layer 23.

Also, according to the semiconductor device 1 of the present embodiment, the shear strength of the first insulating layer 13 and the second insulating layer 23 is equal to or greater than 25 MPa and equal to or less than 35 MPa, which leads to high reliability of the first insulating layer 13 and the second insulating layer 23. In other words, the shear strength of the insulating layers is equal to or greater than 25 MPa and equal to or less than 35 MPa, which leads to high reliability of the insulating layers.

Although embodiments of the present invention have been described in detail above, the present invention is not limited to the embodiments.

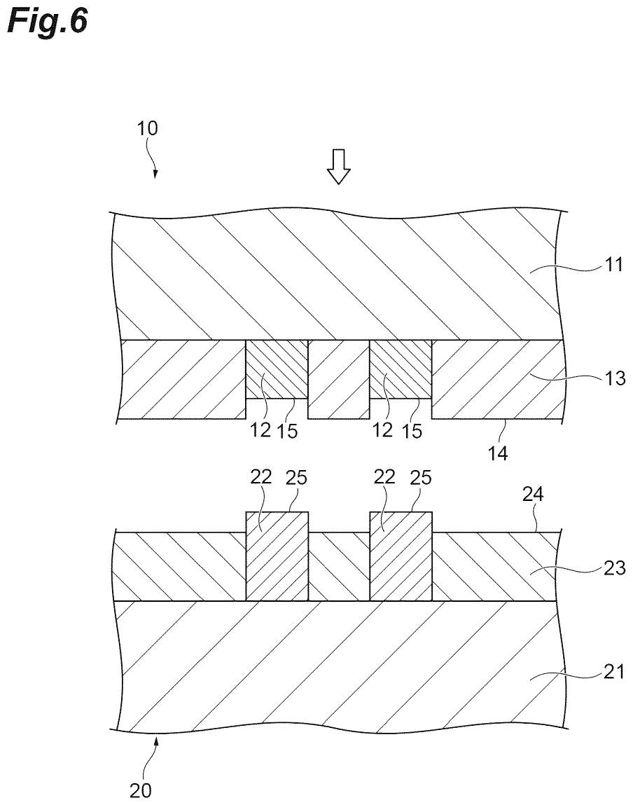

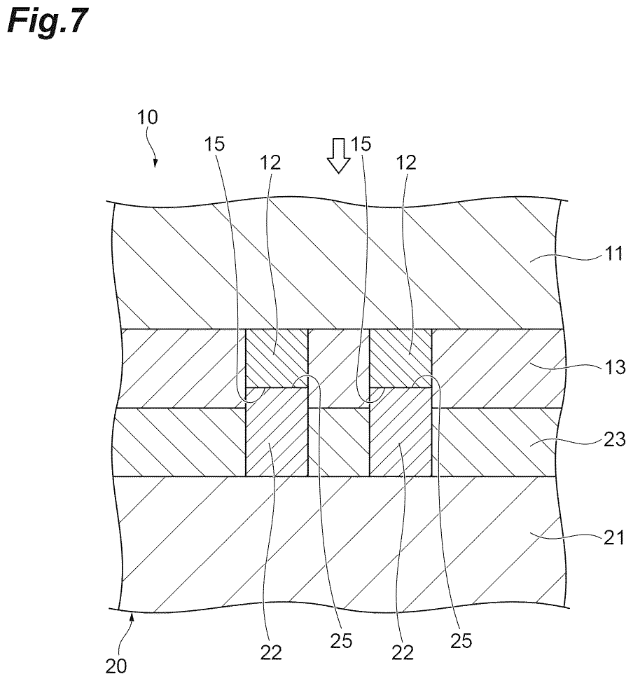

For example, although the embodiment has been described on the assumption that the first semiconductor substrate 10 is disposed above the second semiconductor substrate 20 in the bonding process in the process (e), the second semiconductor substrate 20 may be disposed above the first semiconductor substrate 10 as illustrated in FIGS. 6 and 7. FIGS. 6 and 7 are schematic sectional views illustrating another method for manufacturing the semiconductor device illustrated in FIG. 1. Once the activation of the first surface 14 and the second surface 24 ends, the second semiconductor substrate 20 may be disposed on the bottom side, and the inverted first semiconductor substrate 10 may be disposed on the top side, as illustrated in FIG. 6. In other words, the first semiconductor substrate 10 may be inverted, and the first semiconductor substrate 10 may then be disposed above the second semiconductor substrate 20. Then, the first semiconductor substrate 10 and the second semiconductor substrate 20 may be aligned by fitting the plurality of projecting portions 25 formed on the second surface 24 of the second semiconductor substrate 20 into the plurality of recessed portions 15 formed on the first surface 14 of the first semiconductor substrate 10 in this state as illustrated in FIGS. 6 and 7.

It is possible to increase variations of the method for manufacturing the semiconductor device 1 by disposing the first semiconductor substrate 10 above the second semiconductor substrate 20 or disposing the second semiconductor substrate 20 above the first semiconductor substrate 10.

### REFERENCE SIGNS LIST

1 Semiconductor device
10 First semiconductor substrate
11 First substrate body
12 First electrode
13 First insulating layer (insulating layer)
14 First surface
15 Recessed portion
20 Second semiconductor substrate
21 Second substrate body
22 Second electrode
23 Second insulating layer (insulating layer)
24 Second surface
25 Projecting portion
31 First bonded surface
32 Second bonded surface

1. A method for manufacturing a semiconductor device comprising:
preparing a first semiconductor substrate that includes a first substrate body, a first electrode disposed on the first substrate body, and a first insulating layer disposed around the first electrode on the first substrate body;
preparing a second semiconductor substrate that includes a second substrate body, a second electrode disposed on the second substrate body, and a second insulating layer disposed around the second electrode on the second substrate body;
working a first surface of the first semiconductor substrate on a side opposite to the first substrate body such that the first electrode is recessed with respect to the first insulating layer;
working a second surface of the second semiconductor substrate on a side opposite to the second substrate body such that the second electrode project with respect to the second insulating layer; and
bonding the first electrode of the first semiconductor substrate to the second electrode of the second semiconductor substrate and bonding the first insulating layer of the first semiconductor substrate to the second insulating layer of the second semiconductor substrate.

2. The method for manufacturing a semiconductor device according to claim 1,
wherein the first electrode and the second electrode are formed of copper.

3. The method for manufacturing a semiconductor device according to claim 1,
wherein, in the working of the first surface, the first surface is polished using a CMP method.

4. The method for manufacturing a semiconductor device according to claim 1,
wherein, in the working of the second surface, the second surface is polished using a CMP method.

5. The method for manufacturing a semiconductor device according to claim 1,
wherein the bonding includes activating the first surface and the second surface.

6. The method for manufacturing a semiconductor device according to claim 1.
wherein the bonding includes aligning the first semiconductor substrate with the second semiconductor substrate by fitting projecting portions formed on the second surface and obtained by the second electrode projecting with respect to the second insulating layer into recessed portions formed on the first surface and obtained by the first electrode being recessed with respect to the first insulating layer.

7. The method for manufacturing a semiconductor device according to claim 1,
wherein the first insulating layer is formed of an inorganic insulating material.

8. The method for manufacturing a semiconductor device according to claim 1.
wherein the first insulating layer is formed of an organic insulating material.

9. The method for manufacturing a semiconductor device according to claim 1,
wherein the second insulating layer is formed of an inorganic insulating material.

10. The method for manufacturing a semiconductor device according to claim 1,
wherein the second insulating layer is formed of an organic insulating material.

11. The method for manufacturing a semiconductor device according to claim 1,
wherein the first semiconductor substrate is a semiconductor wafer.

12. The method for manufacturing a semiconductor device according to claim 1,
wherein the first semiconductor substrate is a semiconductor chip obtained by singulating a semiconductor wafer.

13. The method for manufacturing a semiconductor device according to claim 1,
wherein the second semiconductor substrate is a semiconductor wafer.

14. The method for manufacturing a semiconductor device according to claim 1,
wherein the second semiconductor substrate is a semiconductor chip obtained by singulating a semiconductor wafer.

15. The method for manufacturing a semiconductor device according to claim 1,
wherein the bonding includes disposing the first semiconductor substrate above the second semiconductor substrate.

16. The method for manufacturing a semiconductor device according to claim 1,
wherein the bonding includes disposing the second semiconductor substrate above the first semiconductor substrate.

17. A semiconductor device comprising:
a first semiconductor substrate including a first substrate body, a first electrode disposed on the first substrate body, and a first insulating layer disposed around the first electrode on the first substrate body; and
a second semiconductor substrate including a second substrate body, a second electrode disposed on the second substrate body, and a second insulating layer disposed around the second electrode on the second substrate body,
wherein the first electrode of the first semiconductor substrate and the second electrode of the second semiconductor substrate are bonded to each other, and the first insulating layer of the first semiconductor substrate and the second insulating layer of the second semiconductor substrate are bonded to each other, and
wherein a first bonded surface between the first electrode and the second electrode are located closer to the side of the first substrate body than a second bonded surface between the first insulating layer and the second insulating layer.

18. The semiconductor device according to claim 17,
wherein shear strength of the first insulating layer and the second insulating layer is equal to or greater than 25 MPa and equal to or less than 35 MPa.

19. A semiconductor device comprising:
a first substrate body;
a first electrode disposed on the first substrate body;
a second substrate body;
a second electrode disposed on the second substrate body and bonded to the first electrode; and
an insulating layer disposed around the first electrode and the second electrode between the first substrate body and the second substrate body,
wherein shear strength of the insulating layer is equal to or greater than 25 MPa and equal to or less than 35 MPa.
